(19) United States
(12) Patent Application Publication
(10) Pub. No.: US 2011/0233508 A1
(43) Pub. Date: Sep. 29, 2011

(54) NONVOLATILE MEMORY DEVICE AND METHOD FOR MANUFACTURING THE SAME

(75) Inventors: Takeshi ARAKI, Tokyo (JP); Takeshi Yamaguchi, Kanagawa-ken (JP)

(73) Assignee: Kabushiki Kaisha Toshiba, Minato-ku (JP)

(21) Appl. No.: 13/045,608

(22) Filed: Mar. 11, 2011

Related U.S. Application Data
(63) Continuation of application No. PCT/JP2008/066603, filed on Sep. 12, 2008.

(51) Int. Cl. H01L 45/00; H01L 21/02

(52) U.S. Cl. 257/4; 438/382; 257/E45.001; 257/E21.004

(57) ABSTRACT

According to one embodiment, a nonvolatile memory device includes an electrode and a memory layer. The memory layer is connected to the electrode, and the memory layer has a resistance configured to change due to a current flowing from the electrode. The electrode includes a first layer and a second layer. The first layer includes a metallic element and a first non-metallic element, and the first non-metallic element has a first valence n. The second layer is provided between the first layer and the memory layer, and the second layer includes the metallic element and a second non-metallic element. The second non-metallic element has a second valence (n+1) greater than the first valence n by 1.

### CROSS-REFERENCE TO RELATED APPLICATIONS

This is a continuation application of International Application PCT/JP2008/066603, filed on Sep. 12, 2008; the entire contents of which are incorporated herein by reference.

### FIELD

Embodiments described herein relate generally to a nonvolatile memory device and a method for manufacturing the same.

### BACKGROUND

In recent years, downsized mobile devices have spread worldwide, and simultaneously, the demand for downsized large-capacity nonvolatile memory has rapidly increased with the drastic progress of high-speed telecommunication networks. Therein, NAND flash memory and downsized HDDs (hard disk drives) in particular have achieved rapid advancements of recording density and are used in various applications such as in the mobile music market, memory for portable game records, memory devices of personal computers, etc. However, it is said that such nonvolatile memory has limitations on increasing the bit density.

Conversely, various memory have been proposed as the next nonvolatile memory device such as memory that utilizes a phase change, uses a magnetic change, utilizes a strong dielectric, utilizes a resistance change, etc. Thereof, there are great expectations for a resistance change memory of so-called ReRAM (Resistive Random Access Memory) to reduce the power consumption and provide drastic improvements to conventional programming and reading speeds by micro-fabrication.

In ReRAM, an electrode is provided to cause a current to flow in a resistance change material used to form a memory layer. In such a case, during the operations of the ReRAM, the electrode on the side causing the current to flow in the memory layer oxidizes; and there are concerns that a high-resistance layer may form particularly at the interface where the electrode contacts the memory layer. Such a high-resistance layer makes the operations of the ReRAM unstable, increases the power consumption, and may, for example, increase the Joule heat generated during reset in which a large current flows which may cause further oxidation and undesirably shorten the life of the ReRAM.

On the other hand, although it is conceivable to use a noble metal such as, for example, Pt that does not oxidize easily as the electrode recited above, the practical usability is low because of high costs and poor processing characteristics. In other words, it is desirable for the electrode recited above to include a metal compound such as, for example, a metal oxide.

Accordingly, there is a strong need for technology to suppress the degradation of the electrode when using an inexpensive metal compound having good processing characteristics.

JP-A 2007-42784 (Kokai) discusses technology that uses a nitride and an oxide such as TiN and ZnO as an electrode contacting a metal oxide layer having a resistance configured to change due to an electrical signal.

### BRIEF DESCRIPTION OF THE DRAWINGS

FIGS. 1A to 1C are schematic views illustrating the configuration of a nonvolatile memory device according to a first embodiment;

FIGS. 2A and 2B are schematic views illustrating the configuration of the nonvolatile memory device according to the first embodiment;

FIGS. 3A and 3B are schematic perspective views illustrating the configurations of other nonvolatile memory devices according to the first embodiment;

FIG. 4 is a schematic perspective view illustrating the state of the electrode surface of the nonvolatile memory device according to the first embodiment;

FIGS. 5A to 5C are schematic cross-sectional views illustrating operations of the nonvolatile memory device according to the first embodiment;

FIG. 6 is a schematic perspective view illustrating the state of the electrode surface of a nonvolatile memory device of a comparative example;

FIGS. 7A to 7C are schematic cross-sectional views illustrating operations of the nonvolatile memory device of the comparative example;

FIG. 8 is a flowchart illustrating a method for manufacturing a nonvolatile memory device according to a second embodiment;

FIGS. 9A to 9D are schematic cross-sectional views in order of the processes, illustrating the method for manufacturing a nonvolatile memory device according to the second embodiment;

FIGS. 10A and 10B are schematic cross-sectional views in order of the processes, continuing from FIG. 9D;

FIG. 11 is a schematic perspective view illustrating the configuration of a nonvolatile memory device according to a third embodiment; and

FIG. 12 is a schematic plan view illustrating the configuration of the nonvolatile memory device according to the third embodiment.

### DETAILED DESCRIPTION

In general, according to one embodiment, a nonvolatile memory device includes an electrode and a memory layer. The memory layer is connected to the electrode, and the memory layer has a resistance configured to change due to a current flowing from the electrode. The electrode includes a first layer and a second layer. The first layer includes a metallic element and a first non-metallic element, and the first non-metallic element has a first valence n. The second layer is provided between the first layer and the memory layer, and the second layer includes the metallic element and a second non-metallic element. The second non-metallic element has a second valence (n+1) greater than the first valence n by 1.

Various embodiments will be hereinafter described with reference to the accompanying drawings.

The drawings are schematic or conceptual; and the relationships between the thicknesses and widths of portions, the proportions of sizes among portions, etc., are not necessarily the same as the actual values thereof. Further, the dimensions and the proportions may be illustrated differently among the drawings, even for identical portions.

In the specification and the drawings of the application, components similar to those described in regard to a drawing thereinabove are marked with like reference numerals, and a detailed description is omitted as appropriate.

### First Embodiment

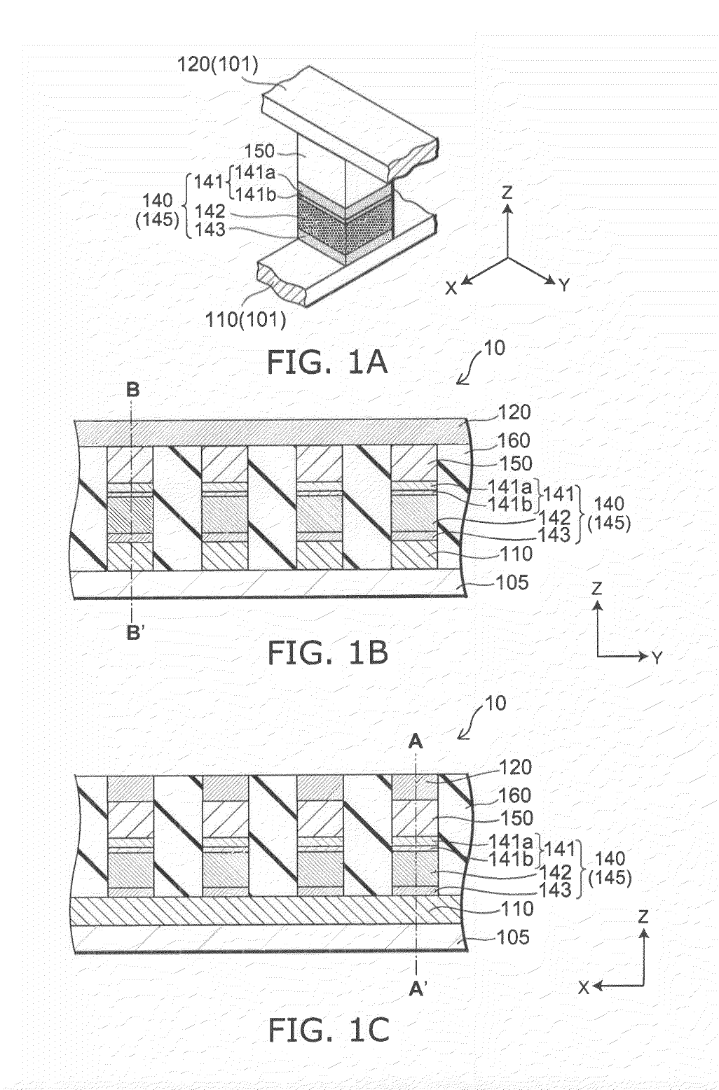

FIGS. 1A to 1C are schematic views illustrating the configuration of a nonvolatile memory device according to a first embodiment.

Namely, FIG. 1A is a schematic perspective view of the main components; FIG. 1B is a cross-sectional view along line A-A′ of FIG. 1C; and FIG. 1C is a cross-sectional view along line B-B′ of FIG. 1B.

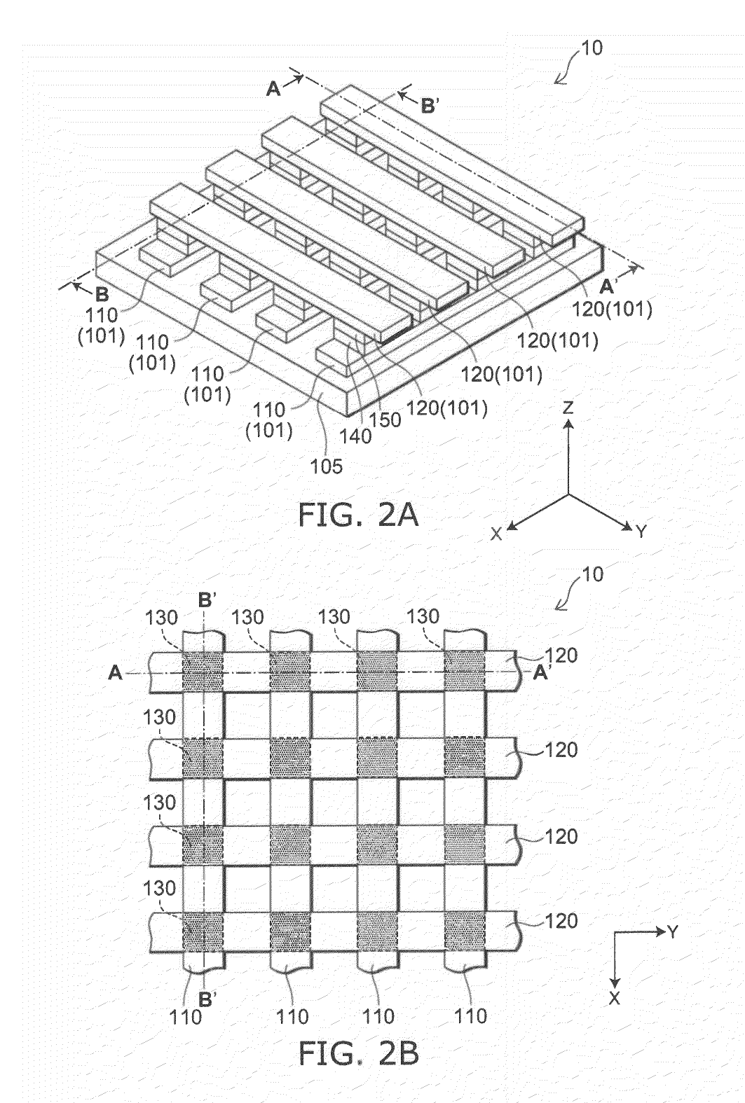

FIGS. 2A and 2B are schematic views illustrating the configuration of the nonvolatile memory device according to the first embodiment.

Namely, FIG. 2A is a schematic perspective view; and FIG. 2B is a plan view.

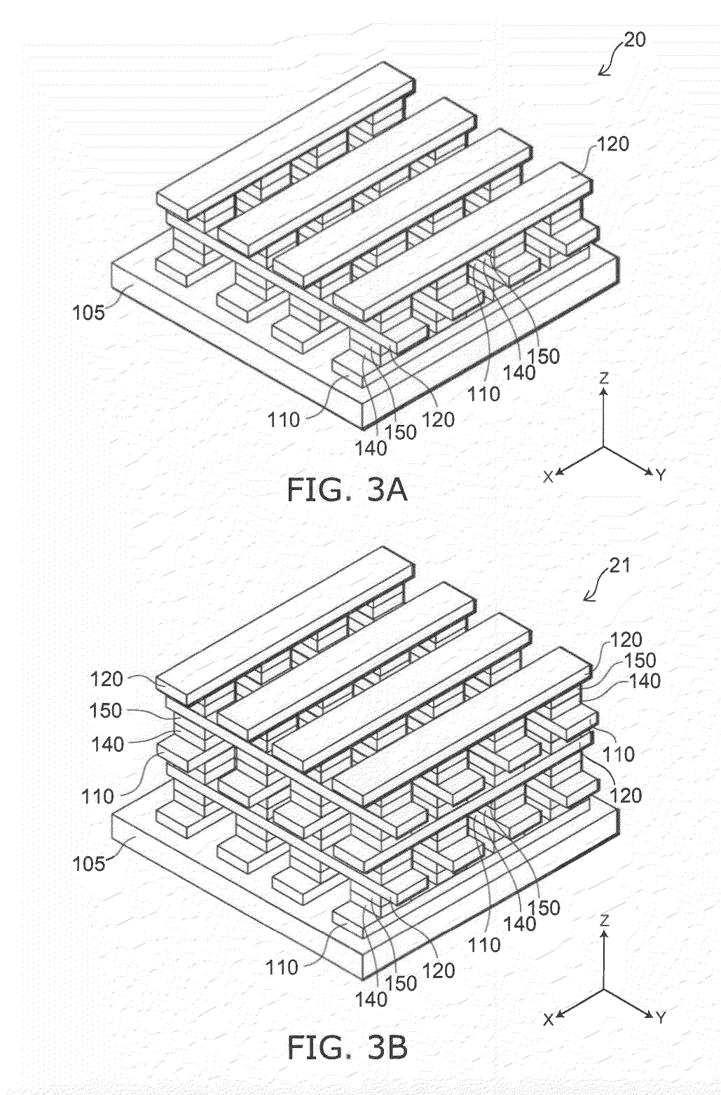

FIGS. 3A and 3B are schematic perspective views illustrating the configurations of other nonvolatile memory devices according to the first embodiment.

The nonvolatile memory device according to the first embodiment is a cross-point nonvolatile memory device.

First, an overview of the configuration of the nonvolatile memory device of the embodiment will be described with reference to FIGS. 1A to 1C and FIGS. 2A and 2B. In the nonvolatile memory device 10 according to the first embodiment as illustrated in FIGS. 2A and 2B, a first interconnect 110 having a band configuration extending in an X-axis direction is provided on a major surface of a substrate 105. A second interconnect 120 having a band configuration extending in a Y-axis direction orthogonal to the X-axis in a plane parallel to the substrate 105 is provided to oppose the first interconnect 110.

Although an example is described above in which the first interconnect 110 and the second interconnect 120 are orthogonal, it is sufficient for the first interconnect 110 and the second interconnect 120 to intersect (to be non-parallel).

Thus, a plane parallel to the major surface of the substrate 105 is taken as the X-Y plane; a direction in which the first interconnect 110 extends is taken as the X-axis; an axis orthogonal to the X-axis in the X-Y plane is taken as the Y-axis; and a direction perpendicular to the X-axis and the Y-axis is taken as a Z-axis.

Although an example is illustrated in FIGS. 2A and 2B in which four of the first interconnects 110 and four of the second interconnects 120 are provided, this is not limited thereto. The number of the first interconnect 110 and the number of the second interconnect 120 are arbitrary. For example, the first interconnect 110 is used as a bit interconnect (BL) and the second interconnect 120 is used as a word line (WL). However, in such a case, the first interconnect 110 may be the word line (WL) and the second interconnect 120 may be the bit line (BL). In the description hereinbelow, the first interconnect 110 is the bit interconnect (BL) and the second interconnect 120 is the word line (WL).

A memory unit 140 is interposed between the first interconnect 110 and the second interconnect 120. In other words, in the nonvolatile memory device 10, the memory unit 140 is provided at intersections 130 (the cross points) formed where the bit interconnects and the word interconnects intersect three-dimensionally.

As illustrated in FIGS. 1A to 1C, the memory unit 140 includes a stacked structural body 145 which includes a first electrode (the electrode) 141, a second electrode 143, and a memory layer 142 provided between the first electrode 141 and the second electrode 143.

The memory layer 142 may include, for example, nickel oxide (NiOₓ), titanium oxide (TiOₓ), ZnMn₂O₄, PrₓCa₁₋ₓMnO₃, and the like that have an electrical resistance value configured to change when a voltage is applied or a current flows. Further, the memory layer 142 may include an oxide including at least one selected from the group consisting of Ti, Ta, Zr, Hf, W, Mo, Ni, Er, Mn, Ir, Nb, Sr, and Ce. However, the embodiment is not limited thereto. The memory layer 142 may include any material that has a change of resistance when a voltage is applied to cause a current to flow in the memory layer 142.

The voltage applied to each of the memory units 140 (each of the stacked structural bodies 145) changes due to the combination of the potential applied to the first interconnect 110 and the potential applied to the second interconnect 120; and information can be stored by the characteristic of the memory unit 140 at this time.

In such a case, a rectifying element unit 150 having, for example, a rectifying characteristic can be provided to provide directionality to the polarity of the voltage applied to the memory unit 140. The rectifying element unit 150 may include, for example, a PIN diode, a MIM (Metal-Insulator-Metal) element, etc. The rectifying element unit 150 may be provided in a region other than the region where the first interconnect 110 opposes the second interconnect 120.

In the case where the memory unit 140 (the stacked structural body 145) and the rectifying element unit 150 are provided between the first interconnect 110 and the second interconnect 120, the stacking order of the memory unit 140 and the rectifying element unit 150 is arbitrary. As described below, in the case where the stacked structure made of the first interconnect 110, the memory unit 140, the rectifying element unit 150, and the second interconnect 120 is multiply provided, the stacking order of the memory unit 140 and the rectifying element unit 150 is arbitrary and may be, for example, the same or different for the memory unit 140 and the rectifying element unit 150 of each of the stacked structures.

The substrate 105 may include, for example, a silicon substrate; and a drive circuit configured to drive the nonvolatile memory device may be provided in the substrate 105.

The first interconnect 110 and the second interconnect 120 may include various electrically conductive materials including metallic elements.

As illustrated in FIG. 1A and FIG. 2B, the memory unit 140 is provided in the region where the first interconnect 110 and the second interconnect 120 intersect three-dimensionally. One memory unit 140 is one component and is called a cell.

As illustrated in FIGS. 1B and 1C, the second interconnect 120 and the memory unit 140 are provided with spacing therebetween in multiple regions; and an insulating unit 160 is provided to be interposed between the multiple regions. The insulating unit 160 is not illustrated in FIG. 1A and FIGS. 2A and 2B.

The insulating unit 160 may include, for example, silicon oxide (SiO₂) having a high electrical resistance, etc. However, this is not limited thereto. The insulating unit 160 may include various materials having electrical resistances higher than that of the memory unit 140.

In the description recited above, at least one selected from the first electrode 141 and the second electrode 143 may be used also as one selected from the first interconnect 110 and the second interconnect 120. Further, at least one selected from the first electrode 141 and the second electrode 143 may be used also as, for example, a portion of the electrically conductive layer used to form the rectifying element unit 150.

As recited above, the nonvolatile memory device 10 according to the embodiment includes the stacked structural body 145 including the electrode (the first electrode 141) and the memory layer 142 and a voltage application unit 101 (i.e., the first interconnect 110 and the second interconnect 120) configured to store information by causing a resistance change in the memory layer 142 by applying the voltage and causing the current to flow in the memory layer 142.

Although only one layer of the stacked structural body in which the first interconnect 110, the second interconnect 120, and the memory unit 140 therebetween are stacked is illustrated in FIGS. 1A to 2B recited above, a high density memory device can be formed by stacking many such stacked structural bodies.

In other words, other than a two-layered stacked structural body such as that of a nonvolatile memory device 20 illustrated in FIG. 3A and a four-layered structure such as that of the nonvolatile memory device 21 illustrated in FIG. 3B, the nonvolatile memory device according to the embodiment may include a structure having more layers. Hereinbelow, the nonvolatile memory device 10 illustrated in FIGS. 1A to 2B is described as an example of the nonvolatile memory device according to the embodiment.

In the nonvolatile memory device 10 according to the embodiment, it is taken that the current flows from the first electrode (the electrode) 141 toward the second electrode 143. In other words, the first electrode 141 causes the current to flow from the first electrode 141 toward the memory layer 142.

In the nonvolatile memory device 10 according to the embodiment, the first electrode 141 includes a first layer 141a and a second layer 141b provided between the first layer 141a and the memory layer 142.

The first electrode 141 includes a metallic element and a first non-metallic element, the first non-metallic element having a first valence n.

The first electrode 141 includes the second layer 141b provided at the interface with the memory layer 142; and the second layer 141b includes the metallic element and a second non-metallic element having a valence (the absolute value thereof) greater than that of the first non-metallic element by 1. The second layer 141b may include the first non-metallic element recited above in addition to the metallic element and the second non-metallic element.

In other words, in the compound made of the metallic element and the first non-metallic element of the second layer 141b, for example, at least a portion of the first non-metallic element may be replaced with the second non-metallic element. However, the embodiment is not limited thereto. It is sufficient for a second non-metallic element having a valence (the absolute value thereof) greater than that of the first non-metallic element by 1 to be included in the first electrode 141 on the side of the interface with the memory layer 142.

Thereby, the oxidation of the first electrode 141 is prevented from progressing; the degradation of the electrode (the first electrode 141) is suppressed; and a nonvolatile memory device having a long operational life is provided.

One example will now be described in which the first non-metallic element recited above is oxygen.

In other words, in the case where the first electrode 141 is made of a metal oxide or an oxide of a metal complex and the memory layer 142 is made of another metal oxide or oxide of a metal complex, the metallic element included in the first electrode 141 cannot move easily and, as a result, the oxide layer of the metallic element can be prevented from enlarging by introducing a group V element such as, for example, nitrogen into the proximity of the interface between the memory layer 142 and the first electrode 141.

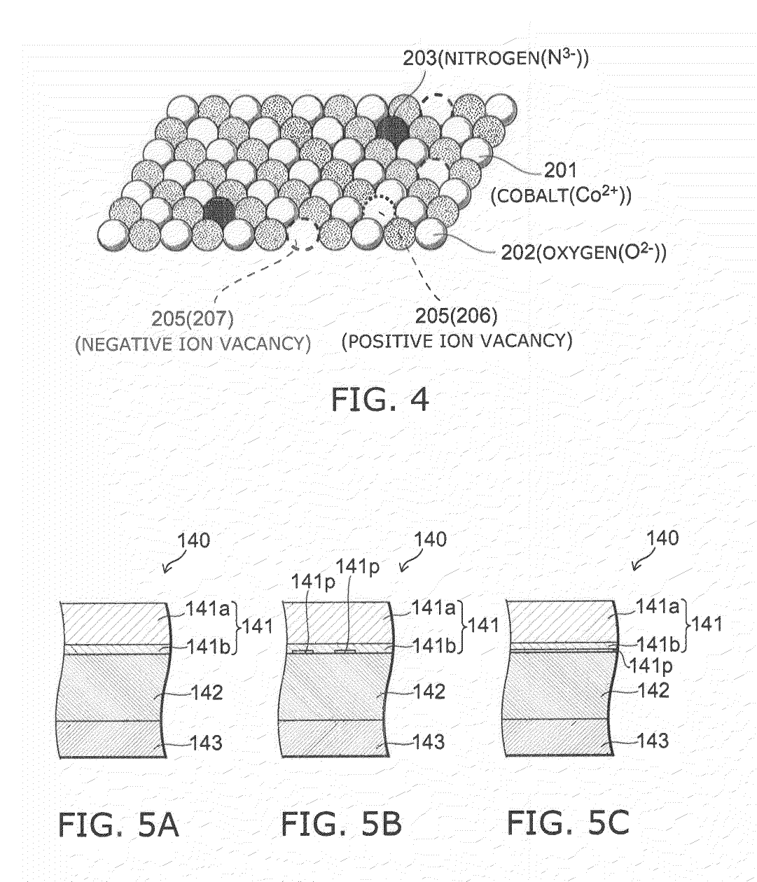

FIG. 4 is a schematic perspective view illustrating the state of the electrode surface of the nonvolatile memory device according to the first embodiment.

As one example, this drawing illustrates the state of the elements of the second layer 141b of the first electrode 141 on the side of the interface with the memory layer 142 for the case where the first electrode 141 is cobalt oxide.

As illustrated in FIG. 4, the first electrode 141 includes cobalt oxide. In other words, a metallic element 201 is cobalt; and a first non-metallic element 202 is oxygen. Nitrogen is contained as a second non-metallic element 203.

In the nonvolatile memory device 10 according to the embodiment in such a case, the second non-metallic element 203 (the nitrogen) having a valence greater than that of the first non-metallic element 202 (the oxygen) by 1 is introduced into the second layer 141b of the first electrode 141. Of the lattice defects 205 of the second layer 141b, the number of first lattice defects (positive ion vacancies) 206 of positive ions corresponding to the metallic element decreases relative to the number of second lattice defects (negative ion vacancies) 207 of negative ions corresponding to the non-metallic element to maintain the electrical neutrality between the lattice defects 205 of the second layer 141b. In other words, the first lattice defects 206 due to deficiencies of cobalt decrease when the number of the nitrogen introduced instead of the oxygen increases. Then, the cobalt of the second layer 141b for which the cobalt density is relatively high does not move easily; and the diffusion rate decreases. For example, for cobalt oxide, the diffusion rate of the cobalt when nitrogen is introduced is reduced to not more than 1/10 to 1/100 of the case where nitrogen is not introduced. Thereby, the progression of the oxidation of the metallic element 201 from the second layer 141b of the first electrode 141 toward the first layer 141a can be suppressed.

FIGS. 5A to 5C are schematic cross-sectional views illustrating operations of the nonvolatile memory device according to the first embodiment.

Namely, FIG. 5A illustrates the initial state of the memory unit 140 of the nonvolatile memory device 10; FIG. 5B illustrates a state in which the memory operation is repeated a prescribed number of times; and FIG. 5C illustrates a state in which the memory operation is repeated more times than that of FIG. 5B.

In the initial state of the nonvolatile memory device 10 as illustrated in FIG. 5A, both the first electrode 141 and the memory layer 142 include an oxide. The first electrode 141 includes a region doped with a group V element at the interface with the memory layer 142, i.e., the second layer 141b.

Then, when the memory operation of the nonvolatile memory device 10 is repeated and the current is provided to the memory layer 142 as illustrated in FIG. 5B, the interface on the memory layer 142 side of the first electrode 141, which causes the current to flow toward the memory layer 142, oxidizes; and an oxide layer 141p may form partially.

In the nonvolatile memory device 10 according to the embodiment at this time, the second layer 141b including the second non-metallic element is provided at the interface on the memory layer 142 side of the first electrode 141. Therefore, in the second layer 141b, the number of the first lattice defects 206 of the positive ions corresponding to the metallic element described in regard to FIG. 4 decreases relatively and the cobalt element does not move easily. Therefore, the growth of the oxide layer 141p occurring at the interface is suppressed. In other words, the progression of the oxide layer 141p into the interior of, for example, the first layer 141a is suppressed.

Therefore, the thickness of the oxide layer 141p produced by the flow of current remains extremely thin. For example, in the nonvolatile memory device 10 according to the embodiment, the thickness of the oxide layer 141p produced by the flow of current is suppressed to be not more than about 1 nm. Thereby, the electrical characteristics of the memory unit 140 due to the partial formation of the oxide layer 141p substantially do not change.

Then, in the case where the driving operation is repeated further and the number of times and the amount of time that the current flows in the memory layer 142 are increased as illustrated in FIG. 5C, the oxide layer 141p may form on the entire surface of the interface between the first electrode 141 and the memory layer 142. However, in such a case as well, the thickness of the oxide layer 141p remains extremely thin; and the thickness of the oxide layer 141p is suppressed to be, for example, not more than about 1 nm as expected. Thereby, the electrical characteristics of the memory unit 140 due to the partial formation of the oxide layer 141p substantially do not change.

Thus, in the nonvolatile memory device 10 according to the embodiment, a thick oxidation thickness of the first electrode 141 can be suppressed by controlling the lattice defects of the interface of the first electrode 141 with the memory layer 142. In other words, according to the nonvolatile memory device 10, degradation of the electrode (the first electrode 141) is suppressed; and a nonvolatile memory device having a long operational life is provided.

### Comparative Example

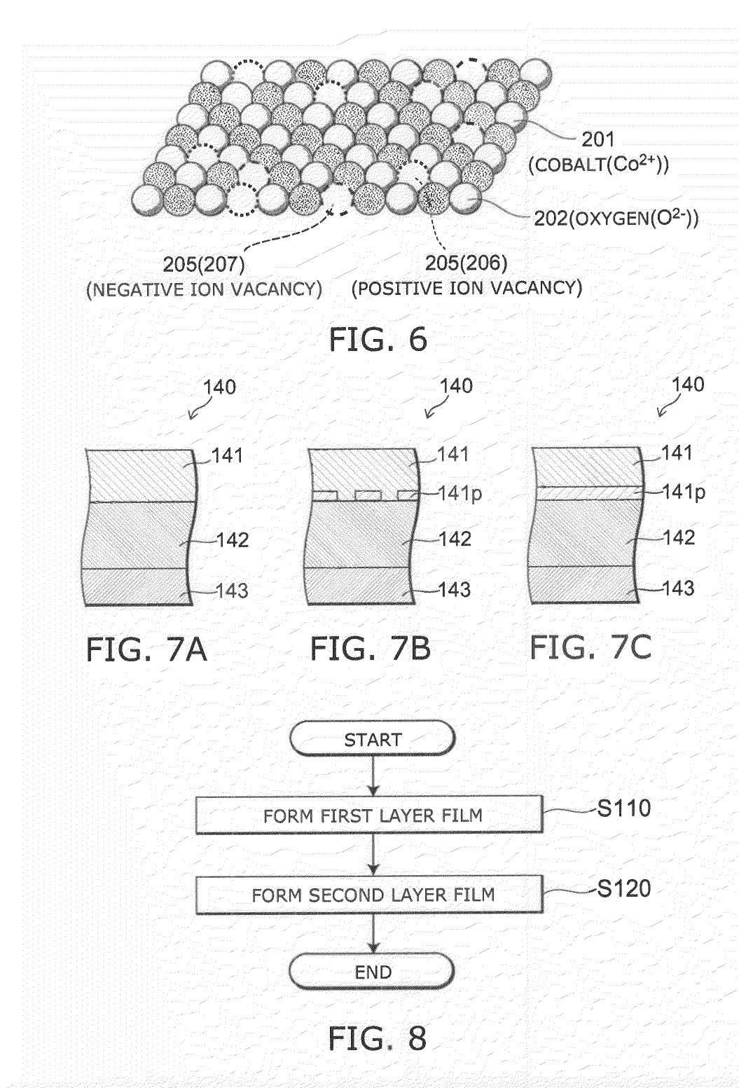

FIG. 6 is a schematic perspective view illustrating the state of the electrode surface of a nonvolatile memory device of a comparative example.

Namely, this drawing illustrates the state of the elements of the second layer 141b of the first electrode 141 on the side of the interface with the memory layer 142 for the case where the first electrode 141 is cobalt oxide.

In the nonvolatile memory device of the comparative example, the second layer 141b is not provided in the first electrode 141 on the side of the interface with the memory layer 142.

As illustrated in FIG. 6, the first electrode 141 of the nonvolatile memory device of the comparative example includes cobalt oxide. In other words, the metallic element 201 is cobalt; and the first non-metallic element 202 is oxygen.

The lattice defects 205 form in the cobalt oxide used to form the first electrode 141. In the lattice defects 205 in such a case, the number of the deficiencies of the metallic element 201 (the cobalt), i.e., the first lattice defects 206 due to the positive ion vacancies, is substantially the same as the number of the deficiencies of the first non-metallic element 202 (the oxygen), i.e., the second lattice defects 207 due to the negative ion vacancies, because of the tendency to maintain the electrical neutrality of the positive ions and the negative ions.

For example, in a prescribed surface area as illustrated in FIG. 6, five of the first lattice defects 206 which are the positive ion vacancies form; and five of the second lattice defects 207 which are the negative ion vacancies form. Thus, in the nonvolatile memory device of the comparative example, many lattice defects form. Thereby, the first electrode 141 oxidizes easily.

FIGS. 7A to 7C are schematic cross-sectional views illustrating operations of the nonvolatile memory device of the comparative example.

Namely, FIG. 7A illustrates the initial state of the memory unit 140 of the nonvolatile memory device; FIG. 7B illustrates a state in which the memory operation is repeated a prescribed number of times; and FIG. 7C illustrates a state in which the memory operation is repeated more times than that of FIG. 7B.

In the initial state of the nonvolatile memory device of the comparative example as illustrated in FIG. 7A, both the first electrode 141 and the memory layer 142 include an oxide.

When the nonvolatile memory device is operated for a constant period of time as illustrated in FIG. 7B, the first electrode 141 that causes the current to flow in the memory layer 142 oxidizes; and the oxide layer 141p forms, for example, partially in the first electrode 141 on the side of the interface with the memory layer 142.

When the current flows from the first electrode 141 into the memory layer 142, the memory layer 142 provides electrons to the first electrode 141. At this time, the memory layer 142 provides electrons to the first electrode 141 after the electrons of the interface of the first electrode 141 with the memory layer 142 move to an inner portion of the interior of the first electrode 141.

At this time, the metallic element 201 included in the first electrode 141 is in a state of being easily oxidized because the sites of the electrons of the interior of the first electrode 141 are empty. In the case where the metallic element 201 is a material oxidizable by the oxygen included in the memory layer 142, oxidation occurs without transferring electrons; and the oxide layer 141p undesirably forms as a resistance layer. In this nonvolatile memory device, the oxidation of the metallic element also occurs easily when Joule heat is generated when the current flows and particularly when a large current flows during the reset.

As the operations continue further as illustrated in FIG. 7C, the thickness of the oxide layer 141p increases; and the oxide layer 141p forms on the entire surface on the memory layer 142 side of the first electrode 141.

Observation by transmission electron spectroscopy shows that the thickness of the oxide layer 141p is 5 nm to 10 nm. In the case where the oxide layer 141p forms with such a thickness, the interface between the first electrode 141 and the memory layer 142 is greatly affected as the electrical conductivity worsens, etc. As a result, the operations of the memory unit 140 become unstable.

Moreover, in the case where a voltage is applied to the memory unit 140 in which such an oxide layer 141p is formed, the consumed current increases by the amount of the resistance of the oxide layer 141p; and heat is generated. Thus, in the nonvolatile memory device of the comparative example, a thick oxide layer 141p forms due to the current flowing in the memory layer 142; the oxide layer 141p causes increased resistance and unstable operations; and in some cases, this leads to heat generation and a shorter life of the nonvolatile memory device itself.

Conversely, in the nonvolatile memory device 10 according to the embodiment as illustrated in FIG. 4, for example, two nitrogens are introduced into the positions of two oxygens of the nonvolatile memory device of the comparative example illustrated in FIG. 6. Therefore, as described above, four cobalts are introduced to maintain the electrical neutrality. As a result, the first lattice defects 206 which are the positive ion vacancies are reduced to one; and there are three of the second lattice defects 207 which are the negative ion vacancies.

Thus, in the nonvolatile memory device 10 according to the embodiment, the number of the first lattice defects 206 can be reduced markedly to ⅕ of that of the nonvolatile memory device of the comparative example.

In other words, in the second layer 141b, the density of the defects of the cobalt decreases; the cobalt does not move easily; and the diffusion rate decreases.

Thereby, as described above, the oxidation of a thick first electrode 141 can be suppressed at the interface of the first electrode 141 with the memory layer 142; the degradation of the electrode (the first electrode 141) is suppressed; and a nonvolatile memory device having a long operational life is provided.

For example, due to the effects of the embodiment, the thickness of the oxide layer 141p which may form in the first electrode 141 is not more than half of that of the comparative example. The number of the first lattice defects 206 due to the deficiencies of the metallic element is reduced extremely. In the case where the oxidation from the interface into the interior of the first electrode 141 is extremely suppressed, the thickness of the oxide layer 141p is suppressed to have a thickness of about 1 nm which is about ⅕ of that of the comparative example. Thereby, the thickness of the oxide layer 141p is thinner than that of the comparative example even in the case where the oxide layer 141p grows as the number of the memory operations increases and the oxide layer 141p covers the entire surface of the first electrode 141 at the interface with the memory layer 142; and good memory operations can be continued.

Although the second non-metallic element 203 is included in the interface portion on the memory layer 142 side of the first electrode 141 in the nonvolatile memory device 10 according to the embodiment, it is undesirable for the second non-metallic element 203 to be contained over the entire film thickness of the first electrode 141 due to negative effects on the electrical characteristics of the first electrode 141. In other words, in the nonvolatile memory device 10 according to the embodiment, the second layer 141b containing the second non-metallic element is provided with a thin layer thickness at the interface on the memory layer 142 side of the first electrode 141; the electrical characteristics of the first electrode 141 are realized by the first layer 141a; and the thin second layer 141b has a function of preventing the oxidation of the first layer 141a. Thereby, the oxidation of the first electrode 141 can be suppressed while maintaining the electrical characteristics of the first electrode 141.

In other words, in the nonvolatile memory device 10 according to the embodiment, the first electrode 141 configured to cause the current to flow from the electrode toward the memory layer 142 includes: the first layer 141a including the metallic element 201 and the first non-metallic element 202, where the first non-metallic element 202 has the first valence n; and the second layer 141b provided between the first layer 141a and the memory layer 142, where the second layer 141b includes the metallic element 201 and the second non-metallic element 203, and the second non-metallic element 203 has the second valence (n+1) greater than the first valence n by 1. The second layer 141b may further include the first non-metallic element 202.

In other words, in the nonvolatile memory device 10 according to the embodiment, the first electrode 141 configured to cause the current to flow from the electrode toward the memory layer 142 includes the metallic element 201 and the first non-metallic element 202, where the first non-metallic element 202 has the first valence n; and at the interface on the memory layer 142 side, the first electrode 141 includes the second non-metallic element 203 which has the second valence (n+1) greater than the first valence n by 1 in addition to the metallic element 201.

Thereby, as described above, the density of the defects of the metallic element 201 decreases; the metallic element (e.g., the cobalt) does not move easily; and the diffusion rate decreases.

In the description recited above, for example, the first valence n recited above may be 2 and the second valence recited above (n+1) may be 3.

In such a case, for example, the first non-metallic element 202 recited above may be oxygen; and the second non-metallic element 203 recited above may include at least one selected from the group consisting of nitrogen, phosphorus, arsenic, and antimony.

For example, the metallic element 201 may be Co; the first non-metallic element 202 may be oxygen; and the second non-metallic element 203 may be nitrogen and/or phosphorus. In other words, the first electrode 141 is CoO₂ and includes nitrogen and/or phosphorus on the side of the interface with the memory layer 142. Also, the metallic element 201 may be W; the first non-metallic element 202 may be oxygen; and the second non-metallic element 203 may be nitrogen and/or phosphorus. In other words, the first electrode 141 may be WO₃ including nitrogen and/or phosphorus on the side of the interface with the memory layer 142.

In the case where the second non-metallic element 203 recited above includes at least one selected from the group consisting of nitrogen, phosphorus, arsenic, and antimony, the proportion of nitrogen in the second non-metallic element 203 may be not less than 50 mole percent. In other words, the formation of the oxide layer 141p can be suppressed more stably by using a higher amount of nitrogen which is more stable among nitrogen, phosphorus, arsenic, and antimony. The first valence n recited above may be 3; and the second valence (n+1) recited above may be 4.

In such a case, for example, the first non-metallic element 202 recited above may be nitrogen; and the second non-metallic element 203 recited above may include at least one selected from the group consisting of carbon, silicon, and germanium.

For example, the metallic element 201 may be Ti; the first non-metallic element may be nitrogen; and the second non-metallic element 203 may be carbon. In other words, the first electrode 141 is TiN including carbon on the side of the interface with the memory layer 142.

It is desirable for the proportion of the second non-metallic element 203 to the first non-metallic element 202 to be 0.03 mole percent (mol %) to 10 mole percent (mol %). In the case where the proportion of the second non-metallic element 203 to the first non-metallic element 202 is less than 0.03 mol %, the effects provided by the nonvolatile memory device according to the embodiment described above decrease. On the other hand, in the case where the proportion of the second non-metallic element 203 to the first non-metallic element 202 is greater than 10 mol %, different phases occur easily; and electrical contact properties may worsen.

It is more desirable for the proportion of the second non-metallic element 203 to the first non-metallic element 202 to be 0.5 mole percent to 10 mole percent.

It is desirable for the thickness of the second layer 141b to be not less than 0.1 nm and not more than 10 nm. In the case where the thickness of the second layer 141b is thinner than 0.1 nm, the effects provided by the nonvolatile memory device according to the embodiment described above decrease. In the case where the thickness of the second layer 141b is thicker than 10 nm, for example, the electrical resistance of the second layer 141b becomes higher than that of the first layer 141a. As a result, the resistance of the first electrode 141 undesirably increases.

It is more desirable for the thickness of the second layer 141b to be not less than 1 nm and not more than 5 nm.

The metallic element 201 may include at least one selected from the group consisting of Ti, Ta, Zr, Hf, W, Mo, Ni, Er, Mn, Nb, Co, Fe, Cu, Zn, and Sr. In other words, the first electrode 141 includes at least one selected from the group consisting of Ti, Ta, Zr, Hf, W, Mo, Ni, Er, Mn, Nb, Co, Fe, Cu, Zn, and Sr.

The memory layer 142 may include an oxide including at least one selected from the group consisting of Ti, Ta, Zr, Hf, W, Mo, Ni, Er, Mn, Ir, Nb, Sr, and Ce.

The memory layer 142 may include an oxide including not less than two types of metallic elements.

To introduce the second non-metallic element 203 into the second layer 141b, for example, in the case where the first electrode 141 is formed as a film using PLD (Pulsed Laser Deposition) or sputtering, a method may be used in which a portion of the film formation is performed by a process that forms the film using a target into which the material used to form the second non-metallic element is mixed.

For example, a metal oxide doped with the second non-metallic element 203 can be obtained by mixing a trace nitride, etc., used to form the second non-metallic element 203 into, for example, an oxide including the metallic element 201 and the first non-metallic element 202, sintering the target while maintaining the uniformity as much as possible, and by forming a film of this material by forming a plume from the target using a laser or ejecting from the target using sputtering.

In the case where a method such as MOCVD (Metal Organic Chemical Vapor Deposition) is used, the formation of the second layer 141b can be realized by separately preparing a raw material of, for example, a nitrogen compound used to form the second non-metallic element 203 and by performing the film formation. In such a case, the amount of the compound (e.g., the oxide compound) including the metallic element 201 and the first non-metallic element 202 can be reduced according to the increase of the compound (e.g., the nitrogen compound) including the second non-metallic element 203.

In the case where chemical solution deposition such as MOD (Metal Organic Decomposition) is used, such a method is possible by, for example, a nitride used to form the second non-metallic element 203 being dissolved in a coating solution in a range in which precipitation of the raw material does not occur. In such a case as well, similarly to the case of MOCVD, although it is necessary for the amount of the oxygen compound to be reduced by the amount of the increased amount of, for example, the nitrogen compound, the stoichiometry is thereby maintained. Such a method makes it particularly easy to increase the compositional uniformity of the material because of the precipitation from the solution.

In the description recited above, the order of the formation of the first electrode 141 and the formation of the memory layer 142 is arbitrary within the extent of technical feasibility.

For example, in the case where the memory layer 142 made of an oxide is formed after forming the first electrode 141 made of an oxide, a method may be used in which a thin film of, for example, a nitride used to form the second layer 141b is formed using physical vapor deposition after the formation of the first layer 141a of the first electrode 141. In such a case, the film thickness of the second layer 141b is controllable by the film formation time and the film formation conditions; the total thickness of the second layer 141b may be not more than 10 nm; and the layer used to form the memory layer 142 can be formed as a film thereon. Here, the total thickness of the second layer 141b is not more than 10 nm based on observation results of transmission electron spectroscopy showing that oxide films of other oxides forming in the material used to form the memory layer 142 due to the thermal history (e.g., about 500° C. for a total of one hour or 900° C. for several seconds) during the film formation have a film thickness of about 1 nm in low cases and 10 nm in high cases.

In the case where the film used to form the rectifying element unit 150 is formed after forming the memory layer 142, the material used to form the memory layer 142 undergoes a temperature history of 700 to 900° C. for several seconds during the activation of, for example, the diode used to form the rectifying element unit 150. Thereby, the p-type semiconductor and the n-type semiconductor mutually diffuse; and the configuration of the embodiment is realized. At this time, a trace amount of the component of the second non-metallic element (e.g., nitrogen) diffuses also into the interface on the first electrode 141 side of the memory layer 142.

On the other hand, in the case where the first electrode 141 is formed after forming the memory layer 142 as well, various methods similar to those described above can be used. In such a case as well, the second layer 141b including, for example, nitrogen, phosphorus, arsenic, and antimony used to form the second non-metallic element 203 is formed at a distance at which sufficient mutual diffusion due to the thermal history is expected. In other words, these non-metallic layers that are used to form the memory layer 142 are diffused.

In the nonvolatile memory device 10 according to the embodiment, the second non-metallic element 203 (e.g., nitrogen, phosphorus, arsenic, antimony, etc.) is introduced at the interface on the memory layer 142 side of the first electrode 141 to replace the first non-metallic element 202 (e.g., oxygen). In other words, in the case where, for example, nitrogen is introduced into the metal oxide, the nitrogen enters the sites where the oxygen exists. Therefore, movement of the lattice defects occurs to maintain the electrical neutrality. In such a case, if no special substances are newly added to the metallic element, a state is realized in which the defects are plentiful where mainly the oxygen exists because the nitrogen has a valence of 3 which is more than the valence of 2 of the oxygen.

Although the amount of the lattice defects is determined by the substance, the temperature, etc., there are many cases where the total amount of the lattice defects does not greatly change when the doping substance is doped with a small amount. Therefore, in the state in which the metal oxide is doped with a trace amount of the nitrogen, the number of the lattice defects is substantially the same as that prior to the doping; and the lattice defects in areas occupied by the oxygen and the nitrogen, which are the non-metallic sites, increase to maintain the electrical neutrality. Restated, the amount of the lattice defects of the metal sites, i.e., the first lattice defects 206, decreases.

When the amount of the lattice defects of the metal decreases, the metallic element 201 of the first electrode 141 exists densely at the interface between the memory layer 142 and the first electrode 141. Therefore, oxidation is limited for the metallic element 201 existing proximally to the boundary layer even in the case where oxidation occurs.

Otherwise, there is a high possibility that the metallic element 201 of the interior of the first electrode 141 may oxidize due to the defects of the metallic element 201. In such a case, the contact resistance may increase because volume expansion and the like may occur due to the oxidation of the metallic element 201 of the interior of the first electrode 141. Generally, when metal atoms oxidize, the volume expands by about a factor of two because the amount of molecules per unit increases while the density decreases.

Thus, in the embodiment, the oxidation of the first electrode 141 is suppressed by including the second non-metallic element 203 in the first electrode 141 at the interface with the memory layer 142 in the case where, for example, both the memory layer 142 and the first electrode 141 are made of an oxide; and stable operations are possible for long-term operations without increasing the interface resistance.

Similarly, the second non-metallic element 203 (e.g., carbon, silicon, germanium, etc.) may be introduced at the interface on the memory layer 142 side of the first electrode 141 to replace the first non-metallic element 202 (e.g., nitrogen). In such a case as well, by a mechanism similar to that recited above, the oxidation of the first electrode 141 is suppressed; and stable operations are possible for long-term operations without increasing the interface resistance.

In the case where a metal oxide is used as the first electrode 141, it is desirable to use an oxide as the memory layer 142 as well. This is because mutual diffusion or the formation of other compounds, etc., may occur with the oxide of the first electrode 141 when a substance other than an oxide is used as the memory layer 142; and the stability may decrease. Therefore, it is desirable for a material based on an oxide to be included in both the memory layer 142 and the first electrode 141 on the side causing the current to flow in the memory layer 142.

Nonvolatile memory devices of examples according to the embodiment will now be described. Because features of the nonvolatile memory device according to the embodiment relate to the memory unit 140 including the memory layer 142 and the first electrode 141, a description is omitted for the other components, e.g., the first interconnect 110, the second interconnect 120, and the rectifying element unit 150.

### First Example

The nonvolatile memory device of a first example is an example in which the first layer 141a of the first electrode 141 includes TiN and the second layer 141b includes a material of TiO₂ including nitrogen. In other words, in this example, the metallic element 201 is Ti; the first non-metallic element 202 is oxygen; and the second non-metallic element 203 is nitrogen. The doping amount of the nitrogen of the second layer 141b is varied. ZnMn₂O₄ is used as the memory layer 142. The characteristics of the first electrode 141, the memory layer 142, and the memory unit 140 which includes the first electrode 141 and the memory layer 142 will now be described.

A TiN powder was mixed in a TiO₂ powder with molar proportions of the non-metallic elements of 0.010, 0.030, 0.10, 0.30, 1.0, 3.0, 5.0, 10, 20, and 25% and then sintered to construct two-inch diameter targets, respectively. The targets corresponding to the molar proportions of the non-metallic element recited above of 0.010, 0.030, 0.10, 0.30, 1.0, 3.0, 5.0, 10, 20, and 25% are referred to as 1Ta, 1Tb, 1Tc, 1Td, 1Te, 1Tf, 1Tg, 1Th, 1Ti, and 1Tj, respectively.

A Si substrate, in which the TiN layer used to form the first layer 141a of the first electrode 141 was provided, was placed inside a vacuum chamber; and film formation was performed by PLD using each of the targets 1Ta to 1Tj recited above. At this time, the temperature of the Si substrate was 500° C.; the oxygen conditions were 1×10⁻¹ Pa; and the laser output was 130 mJ/mm². The film thickness was formed to be about 10 nm by adjusting the film formation time. Thereby, samples were obtained in which the second layer 141b was formed as a film on the TiN layer of the silicon substrate in which the oxygen (O) of the TiO₂ was replaced with nitrogen (N) with the various component proportions. In other words, the second layer 141b was obtained in which the metallic element 201 was Ti, the first non-metallic element 202 was oxygen, and the second non-metallic element 203 was nitrogen.

The samples obtained corresponding to the targets 1Ta, 1Tb, 1Tc, 1Td, 1Te, 1Tf, 1Tg, 1Th, 1Ti, and 1Tj that were used are referred to as samples 1Tab, 1Tbb, 1Tcb, 1Tdb, 1Teb, 1Tfb, 1Tgb, 1Thb, 1Tib, and 1Tjb. In each of the samples recited above, the content proportion of the nitrogen, which is the second non-metallic element 203, is varied.

A memory layer film used to form the memory layer 142 was formed on the second layer 141b of each of the samples 1Tab, 1Tbb, 1Tcb, 1Tdb, 1Teb, 1Tfb, 1Tgb, 1Thb, 1Tib, and 1Tjb recited above by PLD using a target made of ZnMn₂O₄.

At this time, the film thickness was formed to be about 20 nm by adjusting the film formation time. The film formation temperature was 400° C.; and the partial pressure of oxygen was 1 Pa. The samples thus obtained that correspond to the samples 1Tab, 1Tbb, 1Tcb, 1Tdb, 1Teb, 1Tfb, 1Tgb, 1Thb, 1Tib, and 1Tjb recited above are referred to as samples 1Tar, 1Tbr, 1Tcr, 1Tdr, 1Ter, 1Tfr, 1Tgr, 1Thr, 1Tir, and 1Tjr.

The samples 1Tar, 1Tbr, 1Tcr, 1Tdr, 1Ter, 1Tfr, 1Tgr, 1Thr, 1Tir, and 1Tjr were set inside a vacuum chamber; and Pt pads having circular columnar configurations with diameters of 50 μm were formed as films on the memory layer films by sputtering using a mask. The samples thus obtained that correspond to the samples 1Tar, 1Tbr, 1Tcr, 1Tdr, 1Ter, 1Tfr, 1Tgr, 1Thr, 1Tir, and 1Tjr recited above are referred to as samples 1Tas, 1Tbs, 1Tcs, 1Tds, 1Tes, 1Tfs, 1Tgs, 1Ths, 1Tis, and 1Tjs.

In each of the samples thus obtained, a cut was made in a micro region of the surface of the stacked film; one probe was put in contact with the TiN layer to be electrically connected to the TiN layer; one other probe was put in contact with the Pt pad; and an operational test of the operations as a resistance change element was performed. Namely, the Pt pad side was the positive pole; the TiN layer side was the negative pole; and a current was caused to flow in the first electrode 141 and the memory layer 142 due to a voltage up to a maximum of 3 V. At this time, switching operations were performed by repeatedly switching between the on-state and the off-state; and a switching operation test of switching between ON and OFF 50 thousand times was performed for each of the samples. At this time, a sample was determined to be in an operating state if an average potential difference of not less than 1 V between the states of ON and OFF could be maintained for 100 switching operations of switching between ON and OFF.

Of the samples recited above, the samples 1Tas, 1Ths, 1Tis, and 1Tjs were no longer in the operating state for 10 thousand switching operations or less. On the other hand, it was confirmed that the samples 1Tbs, 1Tcs, 1Tds, 1Tes, 1Tfs, and 1Tgs were in the operating state even at 50 thousand switchings.

In other words, effects are obtained particularly when the number of switchings increases in the case where the amount of the doped nitrogen of the description recited above is 0.030 mol % to 10.0 mol %. In other words, the oxidation of the first electrode 141 is suppressed. On the other hand, it is conceivable that the oxidation prevention capability of the first electrode 141 is insufficient in the case where the amount of the doped nitrogen is less than 0.030 mol %.

### Second Example

In a nonvolatile memory device of a second example, similarly to the first embodiment, the first layer 141a of the first electrode 141 includes TiN; and the second layer 141b includes a material of TiO₂ including nitrogen. However, in the example, ZnMnO₃ is used as the memory layer 142. Similarly to the first example, the doping amount of the nitrogen of the second layer 141b is varied.

First, similarly to the first example, a TiN powder was mixed in a TiO₂ powder with molar proportions of the non-metallic elements of 0.010, 0.030, 0.10, 0.30, 1.0, 3.0, 5.0, 10, 20, and 25% and then sintered to form targets 2Ta, 2Tb, 2Tc, 2Td, 2Tc, 2Tf, 2Tg, 2Th, 2Ti, and 2Tj, respectively.

Similarly to the first example, a Si substrate, in which the TiN layer used to form the first layer 141a of the first electrode 141 was provided, was placed inside a vacuum chamber; and film formation was performed by PLD using the various targets recited above. The conditions at this time were similar to those of the first example.

Thereby, samples were obtained in which the second layer 141b including TiO₂ and TiN at the various component proportions was formed as a film on the TiN layer of the silicon substrate.

The samples obtained corresponding to the targets that were used are referred to as samples 2Tab, 2Tbb, 2Tcb, 2Tdb, 2Teb, 2Tfb, 2Tgb, 2Thb, 2Tib, and 2Tjb, respectively.

A memory layer film used to form the memory layer 142 was formed on the second layer 141b of each of the samples recited above by PLD using a target made of ZnMnO₃. The conditions at this time were similar to those of the first example. The samples thus obtained are referred to as samples 2Tar, 2Tbr, 2Tcr, 2Tdr, 2Ter, 2Tfr, 2Tgr, 2Thr, 2Tir, and 2Tjr, respectively.

Then, similarly to the first example, the Pt pad was formed as a film on the various samples recited above. The samples thus obtained are referred to as samples 2Tas, 2Tbs, 2Tcs, 2Tds, 2Tes, 2Tfs, 2Tgs, 2Ths, 2Tis, and 2Tjs, respectively.

Similarly to the first example, a switching operation test was performed for each of the samples thus obtained.

Of the samples recited above, the samples 2Tas, 2Ths, 2Tis, and 2Tjs were no longer in the operating state at 10 thousand switching operations or less. On the other hand, it was confirmed that the samples 2Tbs, 2Tcs, 2Tds, 2Tes, 2Tfs, and 2Tgs were in the operating state at 50 thousand switchings.

In other words, effects are obtained particularly when the number of switchings increases in the case where the amount of the doped nitrogen recited above is 0.030 mol % to 10.0 mol %.

In other words, the oxidation of the first electrode 141 is suppressed. On the other hand, it is conceivable that the oxidation prevention capability of the first electrode 141 is insufficient in the case where the amount of the doped nitrogen is less than 0.030 mol %.

Thus, effects similar to those of the first example are obtained also for the second example in which the material of the memory layer 142 is different from that of the first example.

### Third Example

In the nonvolatile memory device of a third example, similarly to the first embodiment, the first layer 141a of the first electrode 141 includes TiN; and the second layer 141b includes a material of TiO₂ including nitrogen and phosphorus. The proportions of the doped nitrogen and phosphorus are varied. Similarly to the first example, ZnMn₂O₄ is used as the memory layer 142.

First, a target was prepared in which a TiO₂ target was doped with nitrogen and phosphorus with a total of 1 atomic percent (atm %) calculated as the proportion to the oxygen. At this time, the proportions of nitrogen in the total amount of the nitrogen and the phosphorus were 10, 20, 30, 40, 50, 60, 70, 80, 90, and 100%. Each target had a two-inch diameter. The targets in which the nitrogen proportions were 10, 20, 30, 40, 50, 60, 70, 80, 90, and 100% are referred to as targets 3Ta, 3Tb, 3Tc, 3Td, 3Te, 3Tf, 3Tg, 3Th, 3Ti, and 3Tj, respectively.

Then, similarly to the first example, film formation was performed on a Si substrate, in which the TiN layer used to form the first layer 141a of the first electrode 141 was provided, by PLD using each of the targets 3Ta to 3Tj recited above. The conditions at this time were similar to those of the first example. Thereby, samples were obtained in which the second layer 141b including TiO₂, nitrogen, and phosphorus was formed as a film on the TiN layer of the silicon substrate with the various component proportions. In other words, the second layer 141b was obtained in which the metallic element 201 was Ti, the first non-metallic element 202 was oxygen, and the second non-metallic element 203 included at least one selected from nitrogen and phosphorus.

The samples obtained corresponding to the targets are referred to as samples 3Tab, 3Tbb, 3Tcb, 3Tdb, 3Teb, 3Tfb, 3Tgb, 3Thb, 3Tfb, and 3Tfb, respectively. In each of the samples recited above, the content proportions of the nitrogen and the phosphorus in the second non-metallic element 203 are varied.

A memory layer film used to form the memory layer 142 was formed on the second layer 141b of each of the samples recited above by PLD using a target made of ZnMn₂O₄. The conditions at this time were similar to those of the first example. The samples thus obtained are referred to as samples 3Tar, 3Tbr, 3Tcr, 3Tdr, 3Ter, 3Tfr, 3Tgr, 3Thr, 3Tir, and 3Tjr, respectively.

Then, similarly to the first example, the Pt pad was formed as a film on the various samples recited above. The samples thus obtained are referred to as samples 3Tas, 3Tbs, 3Tcs, 3Tds, 3Tes, 3Tfs, 3Tgs, 3Ths, 3Tis, and 3Tjs, respectively.

Similarly to the first example, a switching operation test was performed for each of the samples thus obtained. However, in the operational test of the example, the switching between the on-state and the off-state was repeated 80 thousand times. The determination of the operating state was similar to that of the first example.

Of the samples recited above, the samples 3Tfs, 3Tgs, 3Ths, 3Tis, and 3Tjs were no longer in the operating state at 10 thousand switching operations or less. On the other hand, it was confirmed that the samples 3Tgs, 3Tbs, 2Tcs, 2Tds, and 2Tes were in the operating state even at 80 thousand switchings.

In other words, although large oxidation prevention effects were obtained for the samples in which the amount of the nitrogen as the second non-metallic element 203 was high in the description recited above, it is conceivable that while phosphorus and the like are effective due to being group V elements, other compounds such as phosphoric acid form due to reactivity relationships. It is conceivable that this is why the number of switchings decreased in the case where the amount of phosphorus was relatively higher.

Thus, in the case where the second non-metallic element 203 includes at least one selected from the group consisting of nitrogen, phosphorus, arsenic, and antimony, the proportion of nitrogen in the second non-metallic element 203 may be set to be not less than 50 mole percent. In other words, the formation of the oxide layer 141p can be suppressed more stably by using a higher amount of nitrogen which is more stable among nitrogen, phosphorus, arsenic, and antimony.

### Fourth Example

In a nonvolatile memory device of a fourth example, similarly to the first embodiment, the first layer 141a of the first electrode 141 includes TiN; and the second layer 141b includes a material of CoO₂ including nitrogen. In other words, this is an example in which the metallic element 201 is Co, the first non-metallic element 202 is oxygen, and the second non-metallic element 203 is nitrogen. Similarly to the first example, ZnMn₂O₄ is used as the memory layer 142. The film thickness of the memory layer 142 is varied.

First, a target was prepared in which a CoO₂ target was doped with nitrogen at 1.0 atm % calculated as the proportion to the oxygen.

Then, similarly to the first example, film formation was performed on a Si substrate, in which the TiN layer used to form the first layer 141a of the first electrode 141 was provided, by PLD using the target recited above. The conditions at this time were similar to those of the first example.

Thereby, a sample was obtained in which the second layer 141b including the CoO₂ and nitrogen was formed as a film on the TiN layer of the silicon substrate. The obtained sample is referred to as a sample 4Tab.

A memory layer film used to form the memory layer 142 was formed on the second layer 141b of the sample 4Tab recited above by PLD using a target made of ZnMn₂O₄.

At this time, the film thicknesses were formed to be 5, 10, 15, 20, 25, 30, 40, 50, 75, and 100 nm by adjusting the film formation time. The film formation temperature was 400° C.; and the partial pressure of oxygen was 1 Pa. The samples corresponding to the film thicknesses thus obtained of 5, 10, 15, 20, 25, 30, 40, 50, 75, and 100 nm are referred to as samples 4Tar, 4Tbr, 4Tcr, 4Tdr, 4Ter, 4Tfr, 4Tgr, 4Thr, 4Tfr, and 4Tjr, respectively.

Then, similarly to the first example, the Pt pad was formed as a film on the various samples recited above. The samples thus obtained are referred to as samples 4Tas, 4Tbs, 4Tcs, 4Tds, 4Tes, 4Tfs, 4Tgs, 4Ths, 4Tis, and 4Tjs, respectively.

Similarly to the first example, a switching operation test was performed for each of the samples thus obtained. Namely, 50 thousand repeated switchings were performed in this case.

Only the sample 4Tas was no longer in the operating state at 10 thousand switching operations or less. In other words, it was confirmed that the samples 4Tbs, 4Tcs, 4Tds, 4Tes, 4Tfs, 4Tgs, 4Ths, 4Tis, and 4Tjs were in the operating state even at 50 thousand switchings.

Thus, even in the case where the second layer 141b of the first electrode 141 is a Co-based electrode, effects of oxidation prevention are realized by being doped with nitrogen. It is possible that the number of switchings decreased for the sample 4Tas in which the film thickness of the memory layer 142 was thin due to shorts, etc., between the electrodes.

Thus, even in the case where the first layer 141a is a Co-based oxide and the second layer 141b includes a material of a Co-based oxide including nitrogen in the first electrode 141, the progression of the oxidation of the first electrode 141 can be suppressed.

### Fifth Example

In a nonvolatile memory device of a fifth example, similarly to the first embodiment, the first layer 141a of the first electrode 141 includes TiN; and the second layer 141b includes a material of TiO₂ including nitrogen. However, in the example, Pr₂CaMn₃O₆ is used as the memory layer 142. Similarly to the first example, the doping amount of the nitrogen of the second layer 141b is varied.

First, similarly to the first example, a TiN powder was mixed in a TiO₂ powder with molar proportions of the non-metallic elements of 0.010, 0.030, 0.10, 0.30, 1.0, 3.0, 5.0, 10, 20, and 25% and then sintered to form targets 5Ta, 5Tb, 5Tc, 5Td, 5Te, 5Tf, 5Tg, 5Th, 5Ti, and 5Tj, respectively.

Similarly to the first example, a Si substrate, in which the TiN layer used to form the first layer 141a of the first electrode 141 was provided, was placed inside a vacuum chamber; and film formation was performed by PLD using the various targets recited above. The conditions at this time were similar to those of the first example.

Thereby, samples were obtained in which the second layer 141b including TiO₂ and TiN at the various component proportions was formed as a film on the TiN layer of the silicon substrate.

The samples obtained corresponding to the targets that were used are referred to as samples 5Tab, 5Tbb, 5Tcb, 5Tdb, 5Teb, 5Tfb, 5Tgb, 5Thb, 5Tib, and 5Tjb, respectively.

A memory layer film used to form the memory layer 142 was formed on the second layer 141b of each of the samples recited above by PLD using a target made of Pr₂CaMn₃O₆. The conditions at this time were similar to those of the first example. However, the film formation temperature was 700° C. The samples thus obtained are referred to as samples 5Tar, 5Tbr, 5Tcr, 5Tdr, 5Ter, 5Tfr, 5Tgr, 5Thr, 5Tir, and 5Tjr, respectively.

Then, similarly to the first example, the Pt pad was formed as a film on the various samples recited above. The samples thus obtained are referred to as samples 5Tas, 5Tbs, 5Tcs, 5Tds, 5Tes, 5Tfs, 5Tgs, 5Ths, 5Tis, and 5Tjs, respectively. Similarly to the first example, a switching operation test was performed for each of the samples thus obtained.

Of the samples recited above, the samples 5Tas, 5Ths, 5Tis, and 5Tjs were no longer in the operating state at 10 thousand switching operations or less. On the other hand, it was confirmed that the samples 5Tbs, 5Tcs, 5Tds, 5Tes, 5Tfs, and 5Tgs were in the operating state even at 50 thousand switchings.

In other words, similarly to the first example, effects are obtained particularly when the number of switchings increases in the case where the amount of the doped nitrogen is 0.030 mol % to 10.0 mol %. In other words, the oxidation of the first electrode 141 is suppressed. On the other hand, it is conceivable that the oxidation prevention capability of the first electrode 141 is insufficient in the case where the amount of the doped nitrogen is less than 0.030 mol %.

Although a perovskite-based oxide having a relatively high film formation temperature is used as the material of the memory layer 142 in the example, in this case as well, oxidation prevention effects for the first electrode 141 similar to those of the first example are obtained.

### Second Embodiment

FIG. 8 is a flowchart illustrating a method for manufacturing a nonvolatile memory device according to a second embodiment.

The method for manufacturing the nonvolatile memory device according to the embodiment is a method for manufacturing a device that includes: the stacked structural body 145 including the memory layer 142 and an electrode (the first electrode 141) configured to cause a current to flow toward the memory layer 142; and the voltage application unit 101 configured to store information by causing a resistance change in the memory layer 142 by applying the voltage and causing the current to flow in the memory layer 142.

The voltage application unit 101 recited above may include, for example, the bit interconnect (BL) which is the first interconnect 110 and the word line (WL) which is the second interconnect 120.

In the method for manufacturing the nonvolatile memory device according to the embodiment as illustrated in FIG. 8, first, a first layer film 141af, which is used to form one portion of the electrode (the first electrode 141) and includes the metallic element 201 and the first non-metallic element 202 which has the first valence n, is formed (step S110).

Then, a second layer film 141bf, which is used to form the second layer 141b on the memory layer 142 side which is one other portion of the electrode (the first electrode 141) and includes the metallic element 201 and the second non-metallic element 203 which has the second valence (n+1) greater than the first valence n of the first non-metallic element 202 by 1, is formed (step S120). At this time, the second layer film 141bf may further include the first non-metallic element 202.

Thereby, the second non-metallic element 203 having the valence greater than that of the first non-metallic element 202 by 1 can be included in the first electrode 141 on the side of the interface with the memory layer 142; the degradation of the electrode (the first electrode 141) is suppressed; and a method for manufacturing a nonvolatile memory device having a long operational life is provided.

In the manufacturing method illustrated in FIG. 8, step S120 of forming the second layer film 141bf used to form the second layer 141b is implemented after step S110 of forming the first layer film 141af used to form the first layer 141a of the first electrode 141. In such a case, the forming of the film used to form the memory layer 142 may be implemented after step S120.

However, the order of step S110 and step S120 recited above is interchangeable; and step S110 of forming the first layer film 141af used to form the first layer 141a of the first electrode 141 may be implemented after step S120 of forming the second layer film 141bf used to form the second layer 141b. In such a case, the forming of the film used to form the memory layer 142 is implemented prior to step S120.

For example, the various films used to form the rectifying element unit 150, the film used to form the first interconnect 110, and the film used to form the second interconnect 120 may be formed prior to or after step S110, step S120, and the forming of the film used to form the memory layer 142 recited above.

The case will now be described where the method for manufacturing the nonvolatile memory device according to the embodiment is a method for manufacturing a cross-point nonvolatile memory device in which the stacked structural body 145 including the first electrode 141 and the memory layer 142 is interposed between the first and second interconnects 110 and 120.

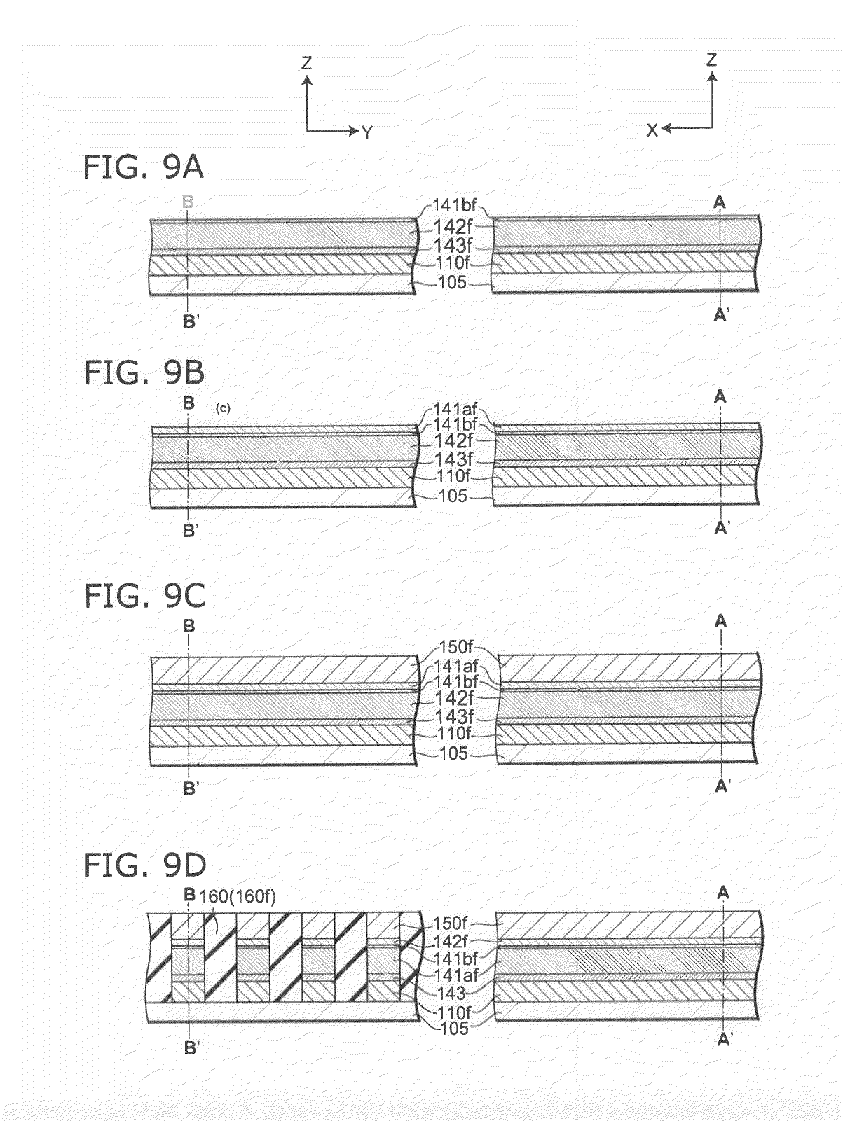

FIGS. 9A to 9D are schematic cross-sectional views in order of the processes, illustrating the method for manufacturing the nonvolatile memory device according to the second embodiment.

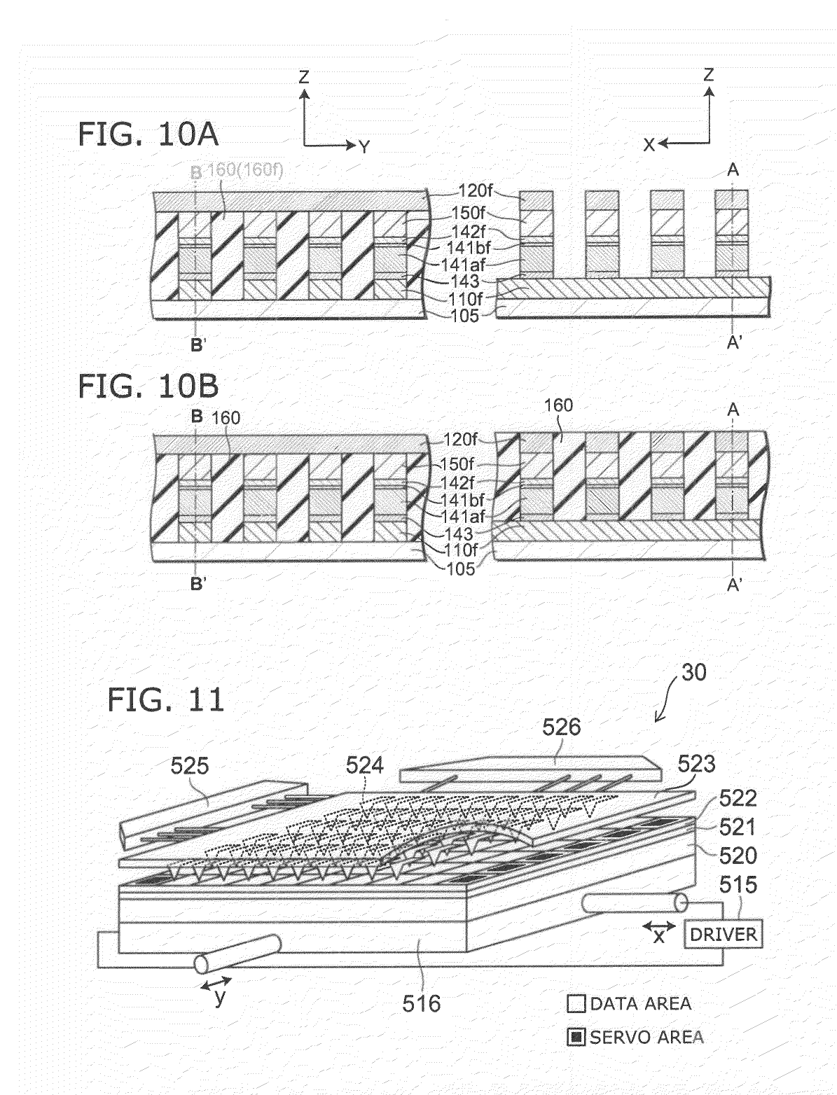

FIGS. 10A and 10B are schematic cross-sectional views in order of the processes, continuing from FIG. 9D.

The left side of each of the drawings of FIG. 9A to FIG. 10B is a cross-sectional view parallel to the Y-axis (a cross-sectional view along line A-A′ of FIGS. 2A and 2B); and the right side of each of the drawings is a cross-sectional view parallel to the X-axis (a cross-sectional view along line B-B′ of FIGS. 2A and 2B).

As illustrated in FIG. 9A, first, a film (a first conductive film 110f) used to form the first interconnect 110 is formed on the substrate 105 made of silicon; a second electrode film 143f used to form the second electrode 143 is formed thereon; a memory layer film 142f used to form the memory layer 142 is formed thereon; and the second layer film 141bf used to form the second layer 141b is formed thereon.

As described above, the first interconnect 110 also can be used as the second electrode 143. In such a case, the first conductive film 110f or the second electrode film 143f recited above can be omitted.

The first conductive film 110f is provided with electrical conductivity at least at the surface of the first interconnect 110 and may include at least one selected from the group consisting of Ti, Ta, Zr, Hf, W, Mo, W, Ni, Pt, Er, Ni, Ir, Ru, Au, Nb, Sr, Si, Ga, and As. Also, an alloy including at least two selected from the group may be used.

The second layer film 141bf includes the metallic element 201 and the second non-metallic element 203. The second non-metallic element 203 has the second valence (n+1) greater than the first valence n of the first non-metallic element 202 by 1. In such a case, the second layer film 141bf may further include the first non-metallic element 202. The second layer film 141bf can be formed using various methods such as, for example, PLD, MOCVD, MOD, etc., as described above.

The process illustrated in FIG. 9A corresponds to step S120 illustrated in FIG. 8.

As illustrated in FIG. 9B, the first layer film 141af used to form the first layer 141a is formed on the second layer film 141bf.

The first layer film 141af may include various materials including the metallic element 201 and the first non-metallic element 202. The metallic element 201 may include at least one selected from the group consisting of Ti, Ta, Zr, Hf, W, Mo, Ni, Er, Mn, Nb, Co, Fe, Cu, Zn, and Sr. The first non-metallic element may include, for example, oxygen and/or nitrogen. The first non-metallic element 202 has the first valence n.

This process corresponds to step S110 illustrated in FIG. 8.

Thus, the manufacturing method illustrated in FIGS. 9A to 9D is an example in which step S110 and step S120 illustrated in FIG. 8 are implemented in the reverse order.

The first layer film 141af recited above can be formed using various methods such as, for example, PLD, MOCVD, MOD, etc., as described above.

For example, the first layer film 141af may be formed on the memory layer film 142f; and subsequently, the second non-metallic element 203 included in the memory layer film 142f may be diffused into the first layer film 141af to form the second layer film 141bf. In such a case, the second layer film 141bf is formed not by a method of depositing a film but by a method of diffusing the second non-metallic element 203. The case will now be described where the method of forming the second layer film 141bf by depositing a film as illustrated in FIG. 9A is used.

Subsequently, as illustrated in FIG. 9C, a rectifying element unit film 150f used to form the rectifying element unit 150 is formed.

The formation of the first conductive film 110f, the second electrode film 143f, the memory layer film 142f, the second layer film 141bf, the first layer film 141af, and the rectifying element unit film 150f recited above may be implemented continuously.

Then, as illustrated in FIG. 9D, the rectifying element unit film 150f, the first layer film 141af, the second layer film 141bf, the memory layer film 142f, the second electrode film 143f, and the first conductive film 110f are patterned using, for example, photolithography and dry etching; a film (an insulating unit film 160f) used to form the insulating unit 160 is formed by CVD (Chemical Vapor Deposition) or coating; and the surface is planarized using CMP (Chemical Mechanical Polishing) if necessary. In the description recited above, the first interconnect 110 is patterned to extend in a direction parallel to the X-axis.

Then, as illustrated in FIG. 10A, a film (a second conductive film 120f) for the second interconnect 120 is formed using sputtering or CVD; and the second conductive film 120f, the rectifying element unit film 150f, the first layer film 141af, the second layer film 141bf, the memory layer film 142f, the second electrode film 143f, and the insulating unit film 160f are patterned using, for example, photolithography and dry etching.

The material of the second interconnect 120 may include, for example, tungsten, tungsten silicide, tungsten nitride, etc. In such a case, these films are patterned to be orthogonal to the patterning direction of the first interconnect 110, that is, such that the second interconnect 120 extends in the Y-axis direction.

Then, as illustrated in FIG. 10B, a film used to form the insulating unit 160 is formed to fill between the memory unit 140 and the like by, for example, forming a SiO₂ film using CVD or coating; and the surface is planarized using CMP if necessary.

Thereby, the nonvolatile memory device 10 having one layer of memory layer 142 illustrated in FIG. 1A to FIG. 3B can be formed.

By repeating the processes recited above, a nonvolatile memory device having multiple layers of the memory units 140 can be formed.

In the description recited above, the rectifying element unit film 150f, the first layer film 141af, the second layer film 141bf, the memory layer film 142f, the second electrode film 143f, and the first conductive film 110f illustrated in FIG. 9D may be patterned; subsequently, the film (the second conductive film 120f) for the second interconnect 120 and the memory unit including the memory layer 142 of the first layer may be formed; subsequently, the rectifying element unit film 150f, the first layer film 141af, the second layer film 141bf, the memory layer film 142f, and the second electrode film 143f of the second layer are formed; and the rectifying element unit film 150f, the first layer film 141af, the second layer film 141bf, the memory layer film 142f, and the second electrode film 143f of the second layer may be patterned simultaneously with the patterning of the second conductive film 120f for the second interconnect 120, the rectifying element unit film 150f, the first layer film 141af, the second layer film 141bf film, the memory layer film 142f, the second electrode film 143f, and the insulating unit film 160f of the first layer such that the second interconnect 120 extends in the Y-axis direction. Thereby, processes can be omitted. Also, this can be implemented repeatedly.

Thus, according to the method for manufacturing the nonvolatile memory device of the embodiment, the degradation of the electrode (the first electrode 141) is suppressed; and a method for manufacturing a nonvolatile memory device having a long operational life is provided.

### Third Embodiment

The third embodiment is a probe memory-type nonvolatile memory device.

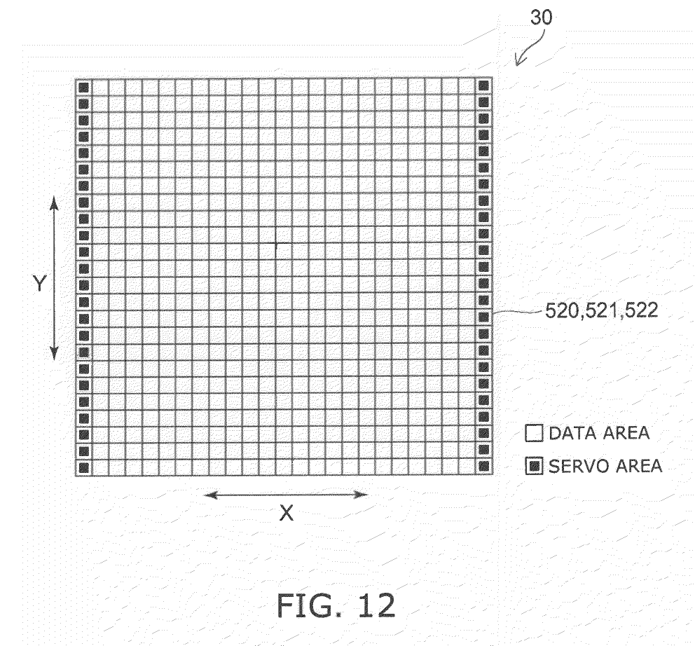

FIG. 11 and FIG. 12 are a schematic perspective view and a schematic plan view illustrating the configuration of the nonvolatile memory device according to the third embodiment.

In the nonvolatile memory device 30 according to the third embodiment as illustrated in FIG. 11 and FIG. 12, a memory unit 522 is provided on a conductive layer 521 and disposed on an XY scanner 516. A probe array is disposed to oppose the memory unit 522.

The probe array includes a substrate 523 and multiple probes (heads) 524 disposed in an array configuration on one face side of the substrate 523. Each of the multiple probes 524 is formed from, for example, a cantilever and is driven by multiplex drivers 525 and 526.

Although each of the multiple probes 524 is individually operable using a microactuator inside the substrate 523, all of the multiple probes 524 may be operated collectively with the same operation to access a data area of the memory medium.

First, all of probes 524 are operated back and forth at a constant period in the X direction using the multiplex drivers 525 and 526; and the positional information in the Y direction is read from the servo area of the memory medium. The positional information in the Y direction is transferred to a driver 515.

The driver 515 drives the XY scanner 516 based on the positional information, moves the memory medium in the Y direction, and performs positional alignment between the memory medium and the probes.

When the positional alignment thereof is completed, data is read or programmed simultaneously and continuously for all of the probes 524 on the data area.

The data can be read and programmed continuously because the probes 524 operate back and forth in the X direction. The reading and the programming of the data is implemented one row at a time for the data area by sequentially changing the Y direction position of the memory unit 522.

The memory unit 522 may be moved back and forth at a constant period in the X direction; the positional information may be read from the memory medium; and the probes 524 may be moved in the Y direction.

The memory unit 522 is provided on, for example, the conductive layer 521 provided in a substrate 520.

The memory unit 522 includes multiple data areas and servo areas disposed at both X direction ends of the multiple data areas. The multiple data areas make up the main components of the memory unit 522.

Servo burst signals are stored inside the servo areas. The servo burst signals indicate the Y-direction positional information inside the data area.

Further, in addition to such information, an address area in which address data is stored and a preamble area for synchronization are disposed inside the memory unit 522.

The data and the servo burst signal are stored in the memory unit 522 as memory bits (electrical resistance fluctuations). “1” and “0” information of each memory bit is read by detecting the electrical resistance of the memory unit 522.

In the example, one probe (head) is provided corresponding to one data area; and one probe is provided for one servo area.

The data area includes multiple tracks. Each track of the data area is designated by the address signal read from the address area. The servo burst signal read from the servo areas eliminates reading errors of the memory bits by moving the probes 524 to the center of the track.

Here, it is possible to utilize head position control technology of HDDs by having the X direction correspond to the down-track direction and the Y direction correspond to the track direction.

In the nonvolatile memory device 30 having such a configuration, the memory unit 522 includes the stacked structural body including the electrode (the not-illustrated first electrode 141) and the memory layer (not illustrated). Also, there is provided a voltage application unit configured to store information by causing a resistance change in the memory layer by applying a voltage and causing a current to flow in the memory layer. In this case, the voltage application unit is the conductive layer 521 and the probes 524. In the description recited above, the conductive layer 521 also may be used as the electrode (the first electrode 141) of the memory unit 522.

The electrode (the first electrode 141) of the memory unit 522 causes the current to flow from the electrode toward the memory layer. The electrode includes: the first layer 141a including the metallic element 201 and the first non-metallic element 202 which has the first valence n; and the second layer 141b provided between the first layer 141a and the memory layer 142 and including the metallic element 201, the first non-metallic element 202, and the second non-metallic element 203 which has the second valence (n+1) greater than the first valence n by 1.

Thereby, the oxidation of the first electrode 141 is prevented from progressing; the degradation of the electrode (the first electrode 141) is suppressed; and a nonvolatile memory device having a long operational life is provided.

In the nonvolatile memory device 30 according to the embodiment as well, similarly to the first embodiment, combinations of the metallic element 201, the first non-metallic element 202, and the second non-metallic element 203 are applicable. The second layer 141b and the like can be implemented similarly to the first embodiment.

The method for manufacturing the nonvolatile memory device according to the second embodiment described above can be applied also in the probe memory-type nonvolatile memory device 30 according to the embodiment.

According to the embodiments, degradation of the electrode is suppressed; and a nonvolatile memory device having a long operational life and a method for manufacturing the same are provided.

Hereinabove, exemplary embodiments of the invention are described with reference to specific examples. However, the invention is not limited to these specific examples. For example, one skilled in the art may similarly practice the invention by appropriately selecting specific configurations of components included in nonvolatile memory devices and methods for manufacturing the same from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all nonvolatile memory devices and methods for manufacturing the same practicable by an appropriate design modification by one skilled in the art based on the nonvolatile memory devices and the methods for manufacturing the same described above as embodiments of the invention also are within the scope of the invention to the extent that the purport of the invention is included.

Furthermore, various modifications and alterations within the spirit of the invention will be readily apparent to those skilled in the art. All such modifications and alterations should therefore be seen as within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile memory device, comprising:
an electrode; and
a memory layer connected to the electrode, the memory layer having a resistance configured to change due to a current flowing from the electrode,
the electrode including
a first layer including a metallic element and a first non-metallic element, the first non-metallic element having a first valence n and
a second layer provided between the first layer and the memory layer, the second layer including the metallic element and a second non-metallic element, the second non-metallic element having a second valence (n+1) greater than the first valence n by 1.

2. The device according to claim 1, wherein the first valence n is 2 and the second valence (n+1) is 3.

3. The device according to claim 1, wherein the first non-metallic element is oxygen and the second non-metallic element includes at least one selected from the group consisting of nitrogen, phosphorus, arsenic, and antimony.

4. The device according to claim 3, wherein a proportion of nitrogen in the second non-metallic element is not less than 50 mole percent.

5. The device according to claim 1, wherein the first valence n is 3 and the second valence (n+1) is 4.

6. The device according to claim 1, wherein the first non-metallic element is nitrogen and the second non-metallic element includes at least one selected from the group consisting of carbon, silicon, and germanium.

7. The device according to claim 1, wherein a proportion of the second non-metallic element to the first non-metallic element is not less than 0.03 mole percent and not more than 10 mole percent.

8. The device according to claim 1, wherein a proportion of the second non-metallic element to the first non-metallic element is not less than 0.5 mole percent and not more than 10 mole percent.

9. The device according to claim 1, wherein a thickness of the second layer is not less than 0.1 nm and not more than 10 nm.

10. The device according to claim 1, wherein a thickness of the second layer is not less than 1 nm and not more than 5 nm.

11. The device according to claim 1, wherein the metallic element includes at least one selected from the group consisting of Ti, Ta, Zr, Hf, W, Mo, Ni, Er, Mn, Nb, Co, Fe, Cu, Zn, and Sr.

12. The device according to claim 1, wherein the memory layer includes at least one selected from the group consisting of Ti, Ta, Zr, Hf, W, Mo, Ni, Er, Mn, Ir, Nb, Sr, and Se.

13. The device according to claim 1, wherein the memory layer includes an oxide including not less than two types of metallic elements.

14. The device according to claim 1, wherein a stacked structural body including the electrode and the memory layer is interposed between a word line and a bit line.

15. The device according to claim 1, wherein a probe configured to supply the current to a stacked structural body including the electrode and the memory layer is included.

16. A method for manufacturing a nonvolatile memory device, the device including a stacked structural body including an electrode and a memory layer, the memory layer having a resistance configured to change due to a current flowing from the electrode, the method comprising:
forming a first layer film used to form one portion of the electrode, the first layer film including a metallic element and a first non-metallic element, the first non-metallic element having a first valence n; and
forming a second layer film used to form a second layer, the second layer being one other portion of the electrode on a side of the memory layer, the second layer film including the metallic element and a second non-metallic element, the second non-metallic element having a second valence (n+1) greater than the first valence n by 1.

17. The method according to claim 16, wherein the first valence n is 2 and the second valence (n+1) is 3.

18. The method according to claim 16, wherein the first non-metallic element is oxygen and the second non-metallic element is at least one selected from the group consisting of nitrogen, phosphorus, arsenic, and antimony.

19. The method according to claim 16, wherein the first valence n is 3 and the second valence (n+1) is 4.

20. The method according to claim 16, wherein the first non-metallic element is carbon and the second non-metallic element is at least one selected from the group consisting of carbon, silicon, and germanium.
